(19) United States
(12) Patent Application Publication
(10) Pub. No.: US 2025/0010424 A1
(43) Pub. Date: Jan. 9, 2025

(54) POLISHING APPARATUS AND TRANSPARENT-LIQUID FILLING METHOD

(71) Applicant: EBARA CORPORATION, Tokyo (JP)

(72) Inventors: Masaki KINOSHITA, Tokyo (JP); Shintaro ISONO, Tokyo (JP); Toshiki MIYAKAWA, Tokyo (JP)

(21) Appl. No.: 18/759,408

(22) Filed: Jun. 28, 2024

(30) Foreign Application Priority Data
Jul. 7, 2023 (JP) 2023-112052
Jul. 7, 2023 (JP) 2023-112053

(51) Int. Cl. B24B 37/013; B24B 37/20

(52) U.S. Cl. CPC B24B 37/013; B24B 37/205

(57) ABSTRACT

A polishing apparatus is disclosed. The polishing apparatus can stabilize an optical path in a space between a transparent window of a polishing pad and an optical sensor head, thereby achieving accurate measuring of a film thickness of a workpiece. polishing apparatus includes: a polishing pad having a transparent window configured to allow light to pass therethrough; a polishing table supporting the polishing pad; a polishing head configured to press a workpiece against the polishing pad; and an optical film-thickness measuring system having an optical sensor head disposed below the transparent window, a space formed between the transparent window and the optical sensor head being filled with a transparent liquid.

### CROSS REFERENCE TO RELATED APPLICATION

This document claims priorities to Japanese Patent Application No. 2023-112052 filed Jul. 7, 2023 and Japanese Patent Application No. 2023-112053 filed Jul. 7, 2023, the entire contents of which are hereby incorporated by reference.

### BACKGROUND

A chemical mechanical polishing (CMP) apparatus configured to polish a surface of a workpiece, such as a wafer, is used in a manufacturing process of semiconductor devices. The CMP apparatus includes a polishing pad attached to a polishing table, and a polishing head configured to press the workpiece against a polishing surface of the polishing pad. The CMP apparatus presses the workpiece against the polishing surface of the polishing pad by the polishing head while supplying a polishing liquid (e.g., slurry) onto the polishing pad to thereby place the surface of the workpiece in sliding contact with the polishing surface of the polishing pad. The surface of the workpiece is polished by a chemical action of the polishing liquid and mechanical action(s) of abrasive grains contained in the polishing liquid and/or the polishing pad.

Polishing of the workpiece is terminated when a thickness of a film (e.g., a dielectric film, a silicon layer, etc.), constituting the surface of the workpiece, has reached a target film thickness. The polishing apparatus includes an optical film-thickness measuring system configured to measure the film thickness of the workpiece. The optical film-thickness measuring system is configured to direct light onto the workpiece and receive reflected light from the workpiece by an optical sensor head disposed in the polishing table, produce a spectrum of the reflected light from intensity of the reflected light, and determine the film thickness of the workpiece based on the spectrum of the reflected light.

The polishing pad on the polishing table has a transparent window that constitutes a part of the polishing pad. The transparent window can prevent the polishing liquid and polishing debris on the polishing pad from contacting the optical sensor head. A space exists between the optical sensor head and the transparent window. The light emitted from the optical sensor head is directed to the workpiece through the space and the transparent window, and the reflected light from the workpiece reaches the optical sensor head through the transparent window and the space.

In addition to the polishing liquid, pure water is supplied onto the polishing pad for use in dressing and cleaning of the polishing pad. Liquid, such as the polishing liquid or pure water, may penetrate into the polishing pad made of a foam material and may enter the space between the optical sensor head and the transparent window. The liquid in the space may change a traveling direction of the light or may scatter the light. In particular, if there are bubbles in the liquid in the space, the liquid may change the intensity of the reflected light from the workpiece and may prevent accurate measuring of the film thickness.

### SUMMARY

Therefore, there are provided a polishing apparatus and a transparent-liquid filling method that can stabilize an optical path in a space between a transparent window of a polishing pad and an optical sensor head, thereby achieving accurate measuring of a film thickness of a workpiece.

Embodiments, which will be described below, relate to a technique of polishing a workpiece, such as a wafer, an interconnect substrate, a quadrangular substrate, and more particularly to a technique of directing light to the workpiece through a transparent window of a polishing pad for polishing the workpiece and measuring a film thickness of the workpiece based on spectrum of reflected light from the workpiece.

In an embodiment, there is provided a polishing apparatus comprising: a polishing pad having a transparent window configured to allow light to pass therethrough; a polishing table supporting the polishing pad; a polishing head configured to press a workpiece against the polishing pad; and an optical film-thickness measuring system having an optical sensor head disposed below the transparent window, a space formed between the transparent window and the optical sensor head being filled with a transparent liquid.

In an embodiment, the transparent window has a lower surface including a light-receiving surface configured to receive light from the optical sensor head and a retreat surface located higher than the light-receiving surface.

In an embodiment, the retreat surface surrounds the light-receiving surface.

In an embodiment, the polishing apparatus further comprises a transparent-liquid supply line communicating with the space, the transparent window having a transparent-liquid outlet communicating with the space.

In an embodiment, the polishing apparatus further comprises a transparent-liquid supply line and a transparent-liquid discharge line communicating with the space, the transparent-liquid discharge line extending in the polishing table.

In an embodiment, the polishing apparatus further comprises: a flow-rate measuring device provided in at least one of the transparent-liquid supply line and the transparent-liquid discharge line, the flow-rate measuring device being configured to measure a flow rate of the transparent liquid flowing through the transparent-liquid supply line; and an operation controller electrically coupled to the flow-rate measuring device, the operation controller being configured to generate an alarm signal when a measured value of the flow rate of the transparent liquid falls outside a preset flow rate range.

In an embodiment, the polishing apparatus further comprises: a pressure measuring device provided in at least one of the transparent-liquid supply line and the transparent-liquid discharge line, the pressure measuring device being configured to measure pressure of the transparent liquid flowing through the transparent-liquid supply line; and an operation controller electrically coupled to the pressure measuring device, the operation controller being configured to generate an alarm signal when a measured value of the pressure of the transparent liquid falls outside a preset pressure range.

In an embodiment, there is provided a transparent-liquid filling method comprising: evacuating a space to form a negative pressure in a space that is formed between a transparent window constituting a part of a polishing pad for polishing a workpiece and an optical sensor head of an optical film-thickness measuring system for measuring a film thickness of the workpiece; and supplying a transparent liquid into the space through a transparent-liquid supply line while the negative pressure is formed in the space.

In an embodiment, the transparent liquid is supplied into the space through the transparent-liquid supply line while the space is being evacuated.

In an embodiment, the transparent liquid is supplied into the space through the transparent-liquid supply line after the evacuation of the space is stopped and while the negative pressure is formed in the space.

In an embodiment, the transparent-liquid filling method further comprises stopping the supply of the transparent liquid into the space after the entire space is filled with the transparent liquid.

The transparent liquid filling the space between the transparent window of the polishing pad and the optical sensor head provides a stable optical path within the space, so the optical film-thickness measuring system can measure an accurate film thickness of the workpiece.

The vacuum evacuation of the space between the transparent window of the polishing pad and the optical sensor head can remove moisture and dust present in the space. After the vacuum evacuation of the space, the transparent liquid is supplied into the space, so that the space is filled with the transparent liquid. The transparent liquid filling the space provides a stable optical path in the space. Therefore, the optical film-thickness measuring system can accurately measure a film thickness of the workpiece.

### BRIEF DESCRIPTION OF THE DRAWINGS

FIG. 1 is a schematic diagram showing an embodiment of a polishing apparatus;

FIG. 2 is a cross-sectional view showing a detailed configuration of an optical film-thickness measuring system;

FIG. 3 is an enlarged cross-sectional view of one embodiment of a transparent window and an optical sensor head;

FIG. 4 is an enlarged cross-sectional view showing another embodiment of a transparent window and an optical sensor head;

FIG. 5 is a diagram illustrates an embodiment in which a space between the transparent window and the optical sensor head is filled with pure water;

FIG. 6 is a diagram illustrates an embodiment in which a flow of pure water is formed in the space between the transparent window and the optical sensor head;

FIG. 7 is a diagram showing an embodiment of a transparent-liquid filling method for filling the space between the transparent window and the optical sensor head with pure water;

FIG. 8 is a flow chart illustrating an embodiment of the transparent-liquid filling method;

FIG. 9 is a flow chart illustrating another embodiment of the transparent-liquid filling method;

FIG. 10 is an enlarged cross-sectional view showing another embodiment of the polishing apparatus;

FIG. 11 is an enlarged cross-sectional view showing still another embodiment of the polishing apparatus;

FIG. 12 is an enlarged cross-sectional view showing still another embodiment of the polishing apparatus;

FIG. 13 is an enlarged cross-sectional view showing still another embodiment of the polishing apparatus;

FIG. 14 is an enlarged cross-sectional view showing still another embodiment of the polishing apparatus;

FIG. 15 is a cross-sectional view showing another embodiment of the transparent window;

FIG. 16 is a cross-sectional view showing yet another embodiment of the transparent window;

FIG. 17 is an enlarged cross-sectional view showing still another embodiment of the polishing apparatus; and

FIG. 18 is an enlarged cross-sectional view showing still another embodiment of the polishing apparatus.

### DESCRIPTION OF EMBODIMENTS

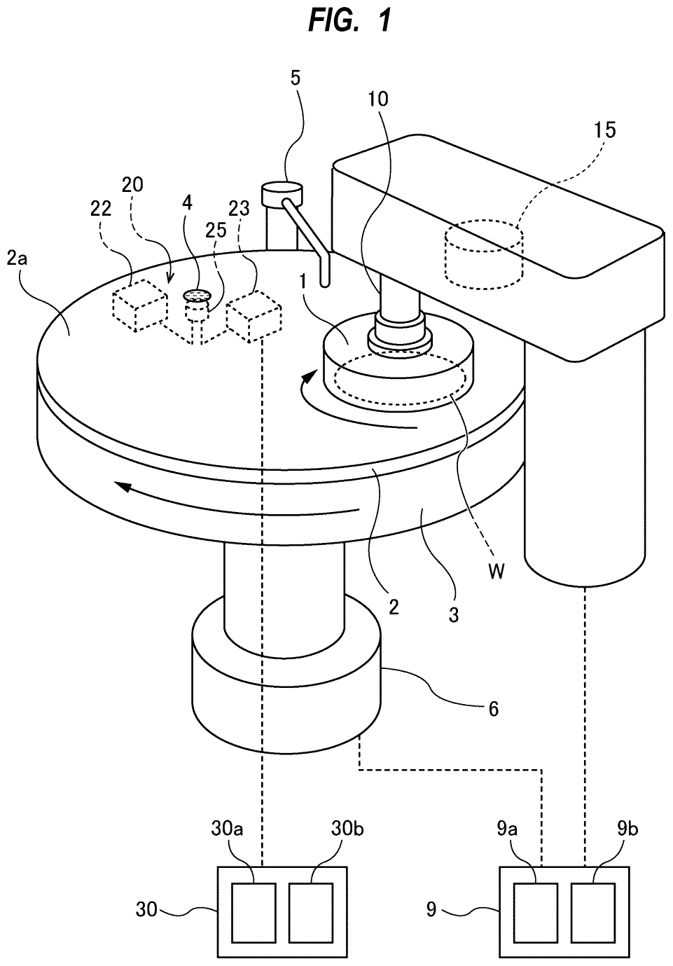

Embodiments will now be described with reference to the drawings. FIG. 1 is a schematic diagram showing an embodiment of a polishing apparatus. As shown in FIG. 1, the polishing apparatus includes a polishing pad 2 having a transparent window 4, a polishing table 3 configured to support the polishing pad 2, a polishing head 1 configured to press a workpiece W against the polishing pad 2, a table motor 6 configured to rotate the polishing table 3, a polishing-liquid supply nozzle 5 configured to supply a polishing liquid, such as slurry, onto the polishing pad 2, and an operation controller 9 configured to control operations of the polishing apparatus.

The polishing pad 2 has an upper surface constituting a polishing surface 2a for polishing the workpiece W. The transparent window 4 constitutes a part of the polishing pad 2 and is made of a transparent material (e.g., transparent resin) that allows light to pass therethrough. The workpiece W has a film that constitutes its surface. Examples of the workpiece W to be polished include a wafer, an interconnect substrate, and a quadrangular substrate used in manufacturing of semiconductor devices.

The polishing head 1 is coupled to a head shaft 10, and the head shaft 10 is coupled to a polishing-head rotating device 15. The polishing-head rotating device 15 is configured to rotate the polishing head 1 together with the head shaft 10 in a direction indicated by an arrow. The configuration of the polishing-head rotating device 15 is not particularly limited. In an example, the polishing-head rotating device 15 includes an electric motor, a belt, and pulleys. The polishing table 3 is coupled to the table motor 6, and the table motor 6 is configured to rotate the polishing table 3 and the polishing pad 2 in a direction indicated by an arrow. The polishing head 1, the polishing-head rotating device 15, and the table motor 6 are coupled to the operation controller 9.

Polishing of the workpiece W is performed as follows. The polishing liquid is supplied from the polishing-liquid supply nozzle 5 onto the polishing surface 2a of the polishing pad 2 on the polishing table 3, while the table motor 6 and the polishing-head rotating device 15 rotate the polishing table 3 and the polishing head 1 in the directions indicated by the arrows in FIG. 1. The workpiece W is pressed against the polishing surface 2a of the polishing pad 2 by the polishing head 1 in the presence of the polishing liquid on the polishing pad 2, while the workpiece W is being rotated by the polishing head 1. The surface of the workpiece W is polished by a chemical action of the polishing liquid and mechanical action(s) of abrasive grains contained in the polishing liquid and/or the polishing pad 2.

The operation controller 9 includes a memory 9a storing programs therein, and an arithmetic device 9b configured to perform arithmetic operations according to instructions contained in the programs. The operation controller 9 is composed of at least one computer. The memory 9a includes a main memory, such as a random-access memory (RAM), and an auxiliary memory, such as a hard disk drive (HDD) or a solid state drive (SSD). Examples of the arithmetic device 9b include a CPU (central processing unit) and a GPU (graphic processing unit). However, the specific configuration of the operation controller 9 is not limited to these examples.

The polishing apparatus includes an optical film-thickness measuring system 20 for measuring a film thickness of the workpiece W. The optical film-thickness measuring system 20 includes a light source 22 configured to emit light, an optical sensor head 25 configured to irradiate the workpiece W with the light from the light source 22 and receive reflected light from the workpiece W, a spectrometer 23 coupled to the optical sensor head 25, and a spectrum processor 30 configured to determine a film thickness of the workpiece W based on a spectrum of the reflected light from the workpiece W. The optical sensor head 25 is disposed within the polishing table 3 and rotates together with the polishing table 3.

The spectrum processor 30 includes a memory 30a storing programs therein, and an arithmetic device 30b configured to perform arithmetic operations according to instructions contained in the programs. The spectrum processor 30 is composed of at least one computer. The memory 30a includes a main memory, such as a random-access memory (RAM), and an auxiliary memory, such as a hard disk drive (HDD) or a solid state drive (SSD). Examples of the arithmetic device 30b include a CPU (central processing unit) and a GPU (graphic processing unit). However, the specific configuration of the spectrum processor 30 is not limited to these examples.

Each of the operation controller 9 and the spectrum processor 30 may be composed of a plurality of computers. For example, each of the operation controller 9 and the spectrum processor 30 may be configured of a combination of an edge server and a cloud server. In one embodiment, the operation controller 9 and the spectrum processor 30 may be comprised of one computer.

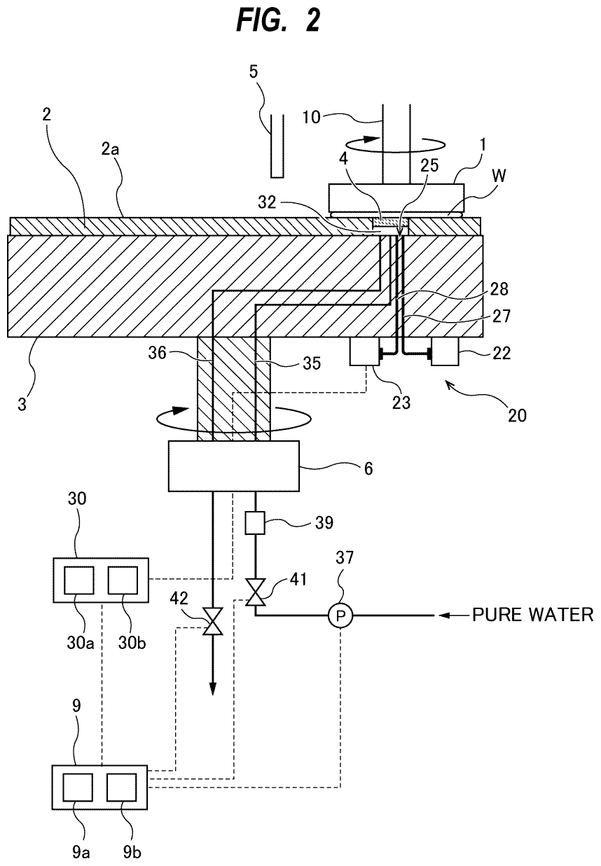

FIG. 2 is a cross-sectional view showing a detailed configuration of the optical film-thickness measuring system 20. The optical sensor head 25 is disposed in the polishing table 3, and the light source 22 and the spectrometer 23 are attached to the polishing table 3. The optical sensor head 25, the light source 22, and the spectrometer 23 rotate together with the polishing table 3 and the polishing pad 2. A position of the optical sensor head 25 is such that the optical sensor head 25 moves across the surface of the workpiece W on the polishing pad 2 each time the polishing table 3 and the polishing pad 2 make one rotation. The optical sensor head 25 is coupled to the light source 22 and the spectrometer 23, and the spectrometer 23 is coupled to the spectrum processor 30.

The optical film-thickness measuring system 20 includes a light-emitting optical fiber cable 27 configured to direct the light, emitted from the light source 22, onto the surface of the workpiece W, and a light-receiving optical fiber cable 28 configured to receive the reflected light from the workpiece W and transmit the reflected light to the spectrometer 23. A distal end of the light-emitting optical fiber cable 27 and a distal end of the light-receiving optical fiber cable 28 are exposed on the polishing table 3. The distal end of the light-emitting optical fiber cable 27 and the distal end of the light-receiving optical fiber cable 28 constitute the optical sensor head 25 that directs the light to the surface of the workpiece W and receives the reflected light from the workpiece W. Other end of the light-emitting optical fiber cable 27 is coupled to the light source 22, and other end of the light-receiving optical fiber cable 28 is coupled to the spectrometer 23. The spectrometer 23 is configured to resolve the reflected light from the workpiece W according to wavelength of the reflected light and measure intensities of the reflected light over a predetermined wavelength range.

The optical sensor head 25 that is constituted by the distal end of the light-emitting optical fiber cable 27 and the distal end of the light-receiving optical fiber cable 28 is located below the transparent window 4 of the polishing pad 2.

The light emitted by the light source 22 travels through the light-emitting optical fiber cable 27, and is emitted from the optical sensor head 25 through the transparent window 4 to the workpiece W. The reflected light from the workpiece W passes through the transparent window 4 and is received by the optical sensor head 25. The reflected light is transmitted to the spectrometer 23 through the light-receiving optical fiber cable 28. The spectrometer 23 resolves the reflected light according to its wavelengths and generates intensity measurement data of the reflected light by measuring the intensity of the reflected light at each of the wavelengths. The intensity measurement data of the reflected light is transmitted from the spectrometer 23 to the spectrum processor 30.

The spectrum processor 30 is configured to generate a spectrum of the reflected light from the workpiece W from the intensity measurement data of the reflected light. The spectrum of the reflected light is expressed as a line graph (i.e., a spectral waveform) representing a relationship between wavelength and intensity of the reflected light. The intensity of the reflected light can also be expressed as a relative value, such as reflectance or relative reflectance.

The spectrum processor 30 is configured to determine the film thickness of the workpiece W based on the spectrum of the reflected light. A known method may be used to determine the film thickness of the workpiece W based on the spectrum. For example, the spectrum processor 30 determines a reference spectrum that is closest in shape to the spectrum of the reflected light from a reference spectrum library, and determines a film thickness associated with the determined reference spectrum. In another example, the spectrum processor 30 performs a Fourier transform on the spectrum of the reflected light, and determines a film thickness from a frequency spectrum obtained.

The polishing apparatus includes a transparent-liquid supply line 35 configured to supply pure water, which is a transparent liquid, into a space 32 formed between the transparent window 4 and the optical sensor head 25, a transparent-liquid discharge line 36 configured to discharge the pure water from the space 32, a supply pump 37 and a transparent-liquid supply valve 41 coupled to the transparent-liquid supply line 35, and a transparent-liquid discharge valve 42 coupled to the transparent-liquid discharge line 36. The transparent-liquid supply line 35 and the transparent-liquid discharge line 36 communicate with the space 32. The transparent-liquid supply line 35 and the transparent-liquid discharge line 36 extend in the polishing table 3. In one embodiment, a plurality of transparent-liquid discharge lines 36 may be provided.

The pure water as a transparent liquid flows from a transparent-liquid supply source (not shown) into the transparent-liquid supply line 35. In one embodiment, the transparent liquid may be a liquid other than pure water as long as the transparent liquid does not prevent light transmission. The supply pump 37 is configured to pressurize the pure water flowing through the transparent-liquid supply line 35. The pure water pressurized by the supply pump 37 is supplied to the space 32 through the transparent-liquid supply line 35. The pure water that has been supplied to the space 32 is discharged from the space 32 through the transparent-liquid discharge line 36.

In one embodiment, the polishing apparatus includes a pressure regulator 39 coupled to the transparent-liquid supply line 35. The pressure regulator 39 is configured to regulate pressure of the pure water as the transparent liquid supplied to the space 32 through the transparent-liquid supply line 35. The pressure of the transparent liquid supplied to the space 32 may be regulated by the supply pump 37. When a utility equipment of a factory in which the polishing apparatus is installed is used as the transparent-liquid supply source, the supply pump 37 may not be provided.

Each of the transparent-liquid supply valve 41 and the transparent-liquid discharge valve 42 is an actuator-driven valve, such as an electric valve, an electromagnetic valve, or an air-operated valve. The transparent-liquid supply valve 41 and the transparent-liquid discharge valve 42 are electrically coupled to the operation controller 9, and operations of the transparent-liquid supply valve 41 and the transparent-liquid discharge valve 42 are controlled by the operation controller 9. In one embodiment, the transparent-liquid supply valve 41 and the transparent-liquid discharge valve 42 may be manual valves.

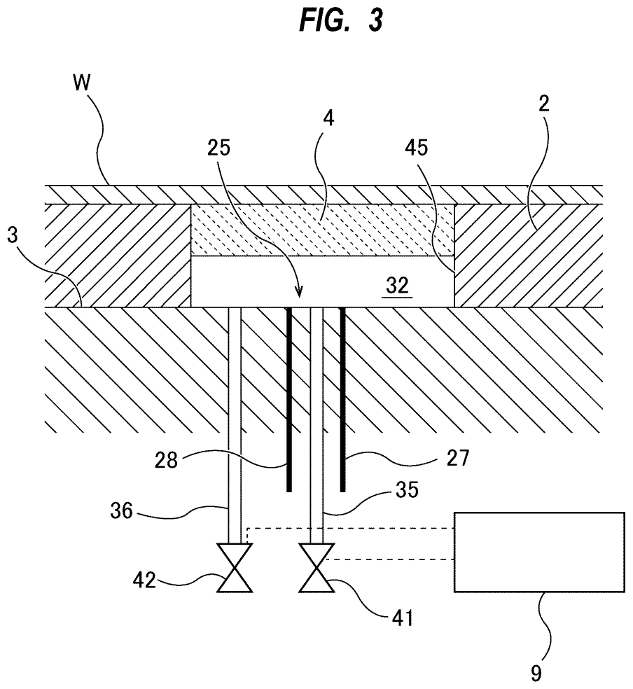

FIG. 3 is an enlarged cross-sectional view showing one embodiment of the transparent window 4 and the optical sensor head 25. As shown in FIG. 3, the transparent window 4 is disposed in a through-hole 45 formed in the polishing pad 2 and closes the through-hole 45. A thickness of the transparent window 4 is smaller than a thickness of the polishing pad 2. A lower surface of the transparent window 4 is located higher than a lower surface of the polishing pad 2. The optical sensor head 25, which is composed of the distal end of the light-emitting optical fiber cable 27 and the distal end of the light-receiving optical fiber cable 28, is located under the transparent window 4 of the polishing pad 2 and faces the space 32.

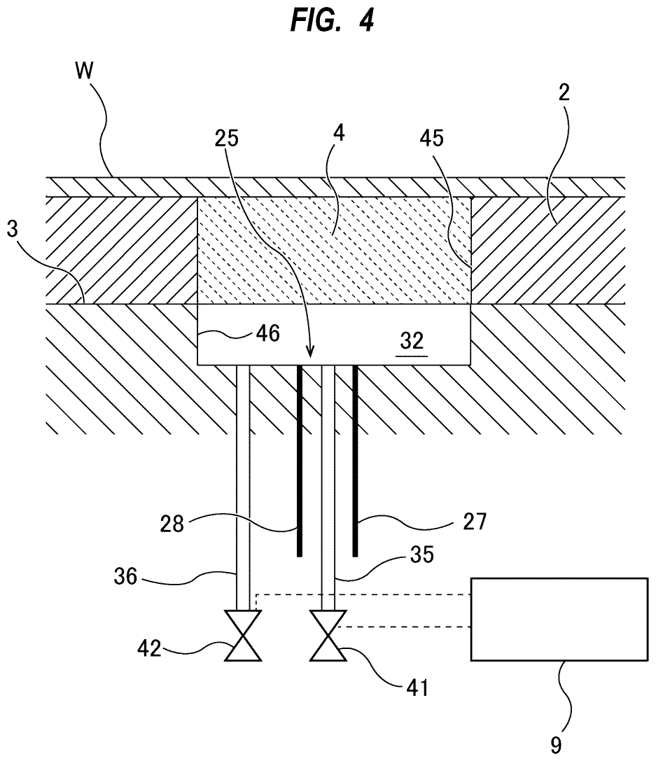

In the embodiment shown in FIG. 3, the space 32 between the transparent window 4 and the optical sensor head 25 is formed in the polishing pad 2. Specifically, the space 32 is defined by the lower surface of the transparent window 4, the through-hole 45 of the polishing pad 2, and an upper surface of the polishing table 3. In one embodiment, as shown in FIG. 4, the space 32 between the transparent window 4 and the optical sensor head 25 may be formed in the polishing table 3. Specifically, the space 32 may be defined by the lower surface of the transparent window 4 and a recess 46 formed in the upper surface of the polishing table 3. In the embodiment shown in FIG. 4, the thickness of the transparent window 4 may be the same as the thickness of the polishing pad 2. In one embodiment, the embodiment shown in FIG. 3 and the embodiment shown in FIG. 4 may be combined.

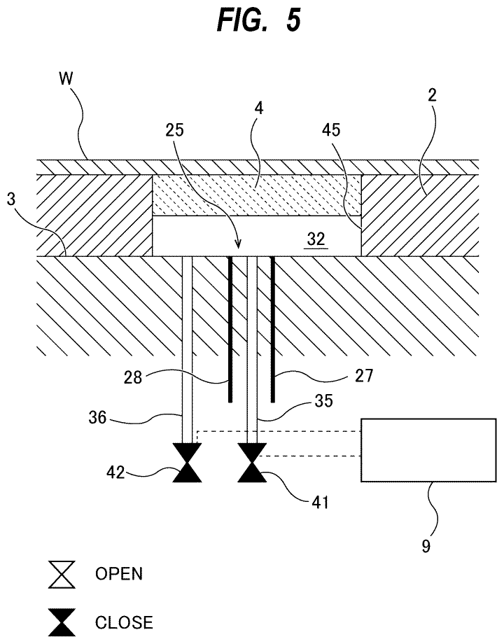

In one embodiment shown in FIG. 5, the space 32 is filled with pure water, which is the transparent liquid. Both the transparent-liquid supply valve 41 and the transparent-liquid discharge valve 42 are closed. Therefore, the pure water is confined in the space 32, and no flow of pure water is formed in the space 32 during polishing of the workpiece W. The light emitted from the optical sensor head 25, which is composed of the distal end of the light-emitting optical fiber cable 27 and the distal end of the light-receiving optical fiber cable 28, passes through the pure water filling the space 32 and the transparent window 4, and irradiates the workpiece W on the polishing pad 2. The reflected light from the workpiece W passes through the transparent window 4 and the pure water filling the space 32 and is received by the optical sensor head 25.

In FIG. 5, the space 32 is filled with the pure water during polishing of the workpiece W. Therefore, a stable optical path for measuring the film thickness of the workpiece W is ensured in the space 32. As a result, the optical film-thickness measuring system 20 can accurately measure the film thickness of the workpiece W.

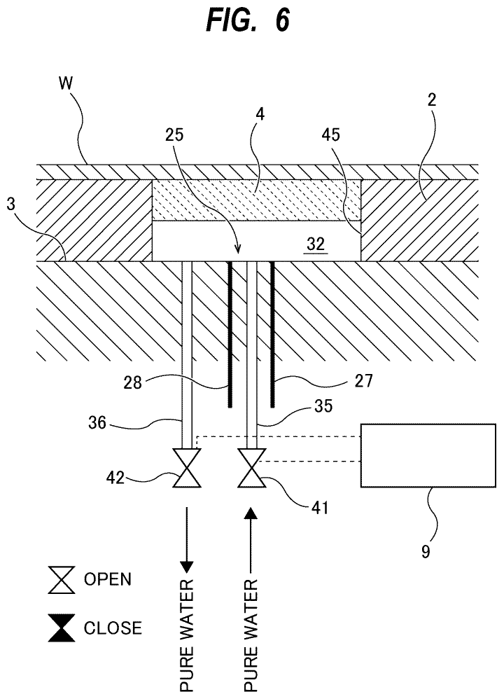

In one embodiment shown in FIG. 6, the space 32 is filled with the pure water which is the transparent liquid, and both the transparent-liquid supply valve 41 and the transparent-liquid discharge valve 42 are open. During polishing of the workpiece W, a flow of pure water is formed in the space 32. Specifically, the pure water flows into the space 32 through the transparent-liquid supply line 35, flows within the space 32, and then flows out of the space 32 through the transparent-liquid discharge line 36. Since the space 32 is filled with the pure water during polishing of the workpiece W, an optical path for measuring the film thickness of the workpiece W is ensured. As a result, the optical film-thickness measuring system 20 can accurately measure the film thickness of the workpiece W.

In the embodiments shown in FIGS. 3 to 6, the transparent window 4 has a flat lower surface. The lower surface of the transparent window 4 is perpendicular to the orientation of the optical sensor head 25. More specifically, the lower surface of the transparent window 4 is perpendicular to the distal end of the light-emitting optical fiber cable 27 and the distal end of the light-receiving optical fiber cable 28 that constitute the optical sensor head 25. Since the lower surface of the transparent window 4 is perpendicular to the optical path of the light emitted from the optical sensor head 25, the light from the optical sensor head 25 is perpendicularly incident on the lower surface of the transparent window 4. In one embodiment, the optical sensor head 25 may be disposed obliquely with respect to the lower surface of the transparent window 4, and the light from the optical sensor head 25 may be obliquely incident on the lower surface of the transparent window 4.

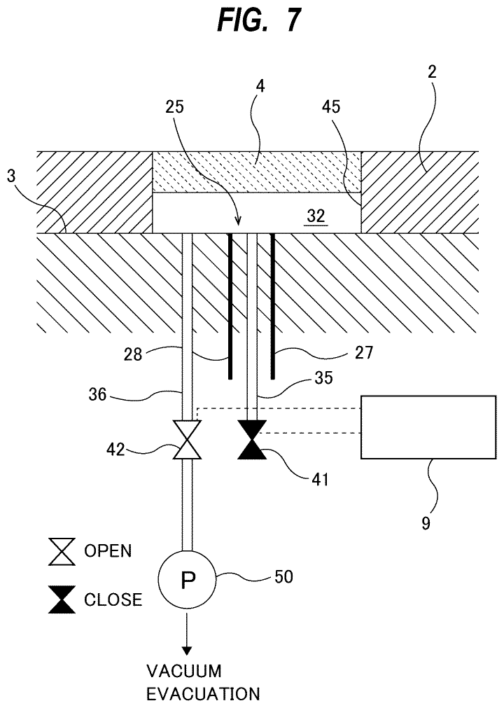

Next, an embodiment of a transparent-liquid filling method for filling the space 32 between the transparent window 4 and the optical sensor head 25 with the pure water, which is an example of the transparent liquid, before polishing of the workpiece W will be described with reference to FIG. 7. First, the transparent-liquid discharge line 36 is coupled to a discharge pump 50. The discharge pump 50 is configured to be capable of pumping liquid and gas. An example of the discharge pump 50 is a piezoelectric pump including a piezoelectric vibrating element.

The transparent-liquid supply valve 41 is closed, and the transparent-liquid discharge valve 42 is opened. When the discharge pump 50 is operated, a negative pressure is produced in the space 32. This vacuum evacuation of the space 32 with the discharge pump 50 can make it possible to remove moisture and dust present in the space 32. In particular, liquid containing bubbles present in the space 32 can be removed by operating the discharge pump 50.

When the transparent-liquid supply valve 41 is opened while the negative pressure is formed in the space 32, the pure water as the transparent liquid is supplied into the space 32 through the transparent-liquid supply line 35. After the entire space 32 is filled with the pure water, the transparent-liquid supply valve 41 is closed to stop the supply of pure water into the space 32. The pure water filling the space 32 provides a stable optical path within the space 32. Therefore, the optical film-thickness measuring system 20 can measure the accurate film thickness of the workpiece W.

The operations of the transparent-liquid supply valve 41 and the transparent-liquid discharge valve 42 are performed by the operation controller 9. In one embodiment, the transparent-liquid supply valve 41 and the transparent-liquid discharge valve 42 may be manual valves, and the operations of the transparent-liquid supply valve 41 and the transparent-liquid discharge valve 42 may be performed manually.

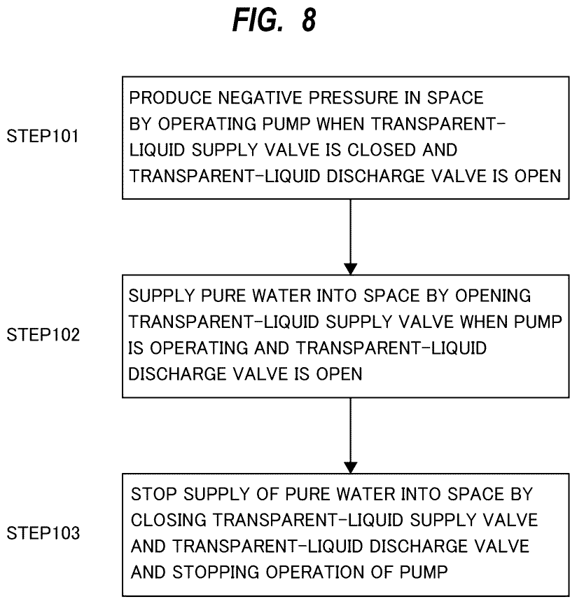

FIG. 8 is a flow chart for explaining one embodiment of the transparent-liquid filling method. In this embodiment, while the space 32 is being evacuated, the pure water as a transparent liquid is supplied into the space 32 through the transparent-liquid supply line 35. Specifically, the process is as follows.

In step 101, when the transparent-liquid supply valve 41 is closed and the transparent-liquid discharge valve 42 is open, and the discharge pump 50 is operated to create a negative pressure in the space 32.

In step 102, while the transparent-liquid discharge valve 42 is open and the discharge pump 50 is operating, the transparent-liquid supply valve 41 is opened. The pure water as the transparent liquid is supplied into the space 32 through the transparent-liquid supply line 35.

In step 103, after the entire space 32 is filled with the pure water, the transparent-liquid supply valve 41 and the transparent-liquid discharge valve 42 are closed, and the operation of the discharge pump 50 is stopped. As a result, the supply of pure water into the space 32 is terminated.

In one embodiment, instead of the operation of the step 103, the discharge pump 50 may be continued to operate with the entire space 32 filled with the pure water, while the transparent-liquid supply valve 41 and the transparent-liquid discharge valve 42 are kept open. In this embodiment, the supply and discharge of pure water to and from the space 32 continue even after the entire space 32 is filled with the pure water. Therefore, a flow of the pure water is formed in the space 32 while the entire space 32 is filled with the pure water.

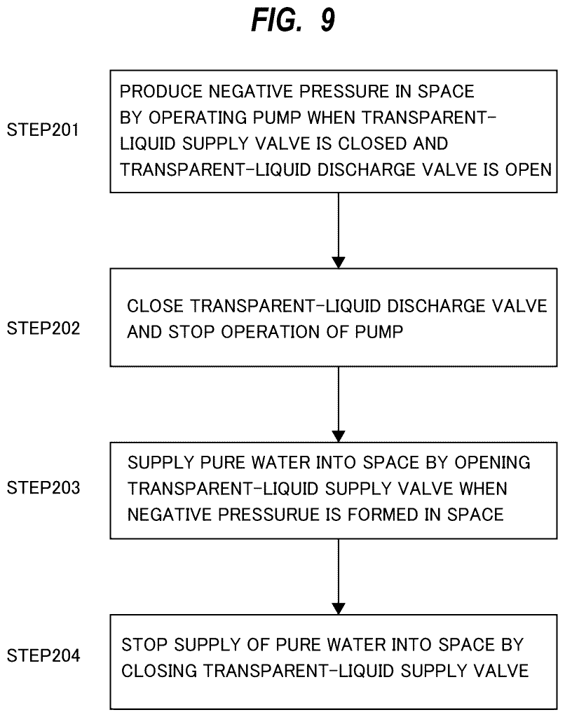

FIG. 9 is a flow chart for explaining another embodiment of the transparent-liquid filling method. In this embodiment, after the evacuation of the space 32 is stopped and when negative pressure is formed in the space 32, the pure water as the transparent liquid is supplied into the space 32 through the transparent-liquid supply line 35. Specifically, the process is as follows.

In step 201, when the transparent-liquid supply valve 41 is closed and the transparent-liquid discharge valve 42 is open, the discharge pump 50 is operated to form negative pressure in the space 32.

In step 202, the transparent-liquid discharge valve 42 is closed and the operation of the discharge pump 50 is stopped.

In step 203, with the negative pressure formed in the space 32, the transparent-liquid supply valve 41 is opened. The pure water as the transparent liquid is supplied into the space 32 through the transparent-liquid supply line 35.

In step 204, after the entire space 32 is filled with the pure water, the transparent-liquid supply valve 41 is closed. As a result, the supply of pure water into the space 32 is terminated.

The embodiments of the transparent-liquid filling method described with reference to FIGS. 7 to 9 are performed before polishing of the workpiece W. In one example, the transparent-liquid filling method described with reference to FIGS. 7 to 9 may be performed after a new polishing pad 2 that is not yet used for polishing of a workpiece is placed on the polishing table 3 and before a workpiece is polished with the new polishing pad 2.

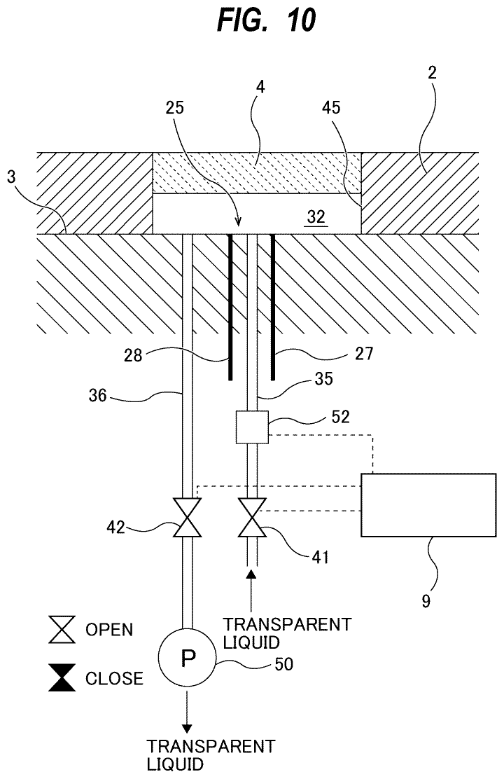

FIG. 10 is an enlarged cross-sectional view showing another embodiment of the polishing apparatus including the transparent window 4 and the optical sensor head 25. Configurations and operations of this embodiment that are not specifically described are the same as those of the above-mentioned embodiments, and therefore duplicated descriptions thereof will be omitted. The polishing apparatus of this embodiment includes an inlet-side measuring device 52 provided in the transparent-liquid supply line 35. The inlet-side measuring device 52 is disposed downstream of the transparent-liquid supply valve 41.

The inlet-side measuring device 52 is configured to measure a physical quantity (i.e., flow rate or pressure) of the transparent liquid flowing through the transparent-liquid supply line 35. The inlet-side measuring device 52 is electrically coupled to the operation controller 9, and a measured value of the physical quantity (flow rate or pressure) of the transparent liquid acquired by the inlet-side measuring device 52 is transmitted to the operation controller 9.

In one embodiment, the inlet-side measuring device 52 is a flow-rate measuring device configured to measure flow rate of the transparent liquid. The operation controller 9 is configured to generate an alarm signal when the measured value of the flow rate of the transparent liquid falls outside a preset flow rate range. The flow rate of the transparent liquid is expected to increase or decrease significantly when a malfunction occurs in the transparent liquid supply system. For example, when the transparent-liquid supply line 35 is clogged or when the supply pump 37 breaks down, the flow rate of the transparent liquid is expected to decrease. On the other hand, when the pressure regulator 39 breaks down or when the transparent liquid leaks through a gap around the transparent window 4, the flow rate of the transparent liquid is expected to increase. If the flow rate of the transparent liquid changes significantly, bubbles may be generated in the transparent liquid and may lower the quality of the intensity measurement data of the reflected light used for the film-thickness measurement. In addition, a change in the flow rate of the transparent liquid may change the pressure of the transparent liquid. If the pressure of the transparent liquid in the space 32 increases, the transparent window 4 may be deformed.

In one embodiment, the inlet-side measuring device 52 is a pressure measuring device configured to measure pressure of the transparent liquid. The operation controller 9 is configured to generate an alarm signal when a measured value of the pressure of the transparent liquid falls outside a preset pressure range.

The operation controller 9 generates an alarm signal when the measured value of the flow rate of the transparent liquid falls outside the preset flow rate range or when the measured value of the pressure of the transparent liquid falls outside the preset pressure range. In one embodiment, the operation controller 9 instructs the optical film-thickness measuring system 20 to stop the measuring of the film thickness of the workpiece W when the measured value of the flow rate of the transparent liquid falls outside the preset flow rate range or when the measured value of the pressure of the transparent liquid falls outside the preset pressure range.

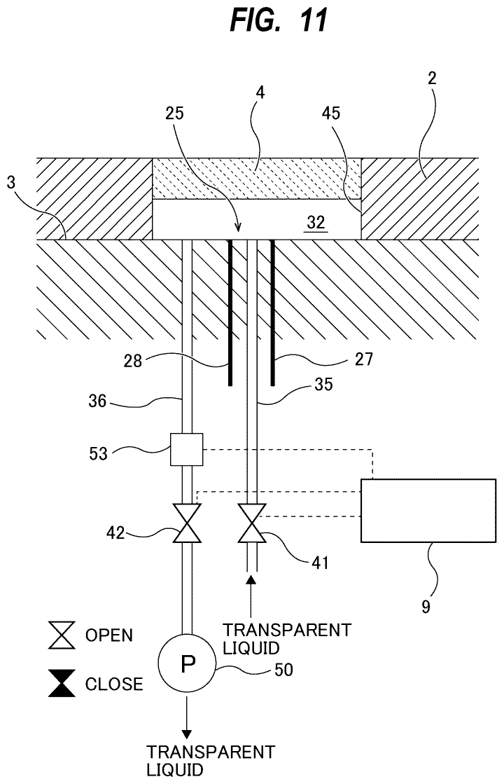

FIG. 11 is an enlarged cross-sectional view showing yet another embodiment of the polishing apparatus including the transparent window 4 and the optical sensor head 25. Configurations and operations of this embodiment that are not specifically described are the same as those of the above-mentioned embodiments, and therefore duplicated descriptions thereof will be omitted. The polishing apparatus of this embodiment includes an outlet-side measuring device 53 provided in the transparent-liquid discharge line 36. The outlet-side measuring device 53 is disposed upstream of the transparent-liquid discharge valve 42.

The outlet-side measuring device 53 is configured to measure a physical quantity (i.e., flow rate or pressure) of the transparent liquid flowing through the transparent-liquid discharge line 36. The outlet-side measuring device 53 is electrically coupled to the operation controller 9, and a measurement value of the physical quantity (flow rate or pressure) of the transparent liquid acquired by the outlet-side measuring device 53 is transmitted to the operation controller 9.

In one embodiment, the outlet-side measuring device 53 is a flow-rate measuring device configured to measure flow rate of the transparent liquid. The operation controller 9 is configured to generate an alarm signal when a measured value of the flow rate of the transparent liquid falls outside a preset flow rate range.

In one embodiment, the outlet-side measuring device 53 is a pressure measuring device configured to measure pressure of the transparent liquid. The operation controller 9 is configured to generate an alarm signal when a measured value of the pressure of the transparent liquid is outside a preset pressure range.

The operation controller 9 generates an alarm signal when the measured value of the flow rate of the transparent liquid falls outside the preset flow rate range or when the measured value of the pressure of the transparent liquid falls outside the preset pressure range. In one embodiment, the operation controller 9 instructs the optical film-thickness measuring system 20 to stop the measuring of the film thickness of the workpiece W when the measured value of the flow rate of the transparent liquid falls outside the preset flow rate range or when the measured value of the pressure of the transparent liquid falls outside the preset pressure range.

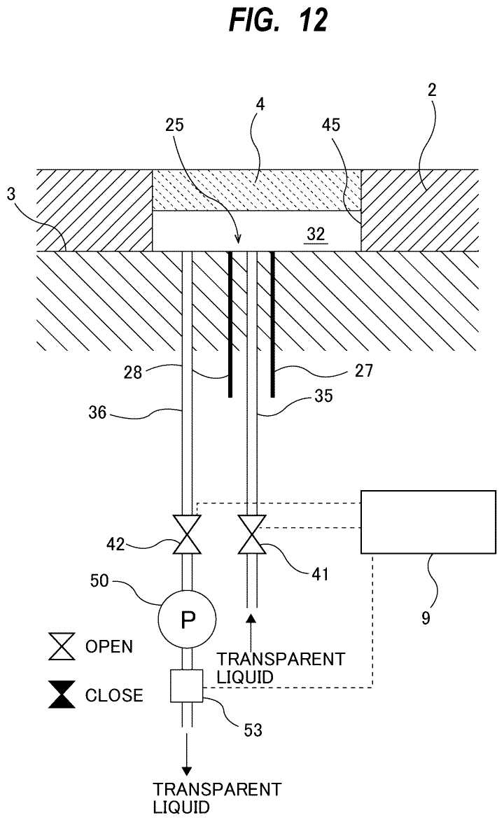

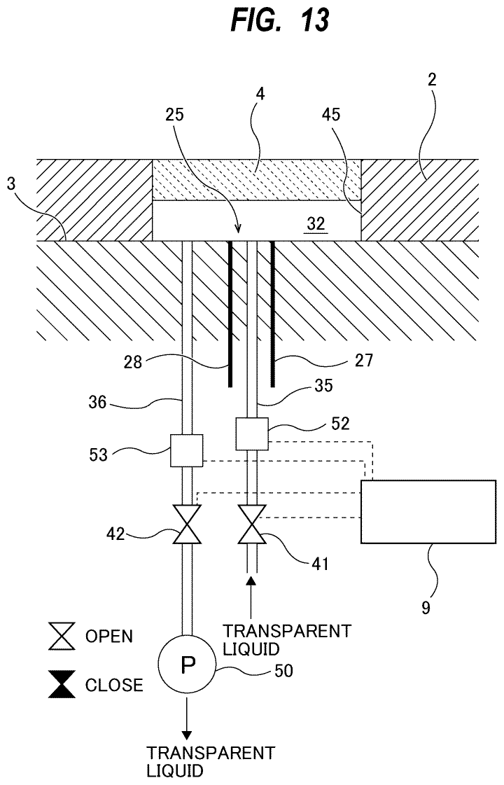

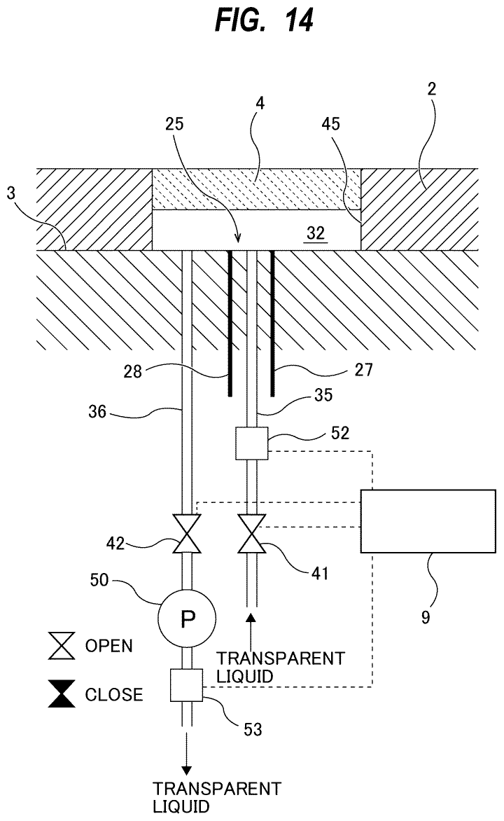

In one embodiment, as shown in FIG. 12, the outlet-side measuring device 53 may be disposed downstream of the transparent-liquid discharge valve 42 and the discharge pump 50. In one embodiment, as shown in FIG. 13, the embodiment of the inlet-side measuring device 52 shown in FIG. 10 may be combined with the embodiment of the outlet-side measuring device 53 shown in FIG. 11, or as shown in FIG. 14, the embodiment of the inlet-side measuring device 52 shown in FIG. 10 may be combined with the embodiment of the outlet-side measuring device 53 shown in FIG. 12.

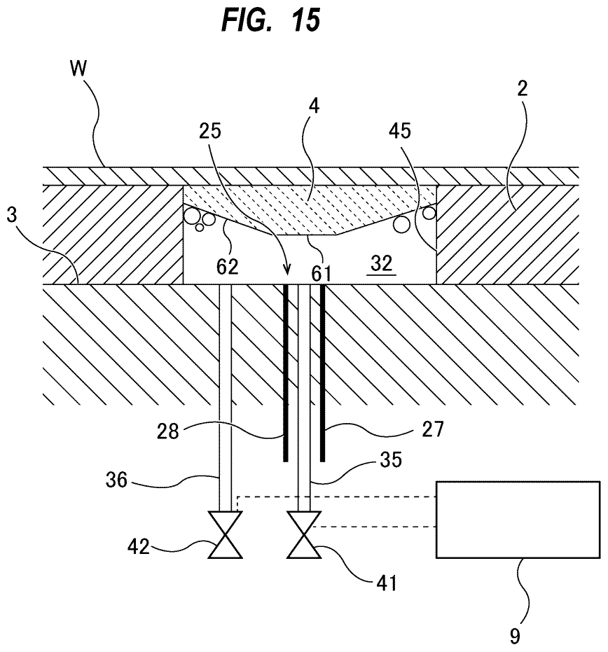

FIG. 15 is a cross-sectional view showing another embodiment of the transparent window 4. Configurations of this embodiment that are not specifically described are the same as those of the embodiments described with reference to FIG. 3 or FIG. 4, and therefore overlapping descriptions thereof will be omitted. As shown in FIG. 15, the transparent window 4 has a lower surface including a light-receiving surface 61 configured to receive the light from the optical sensor head 25, and a retreat surface 62 that is located higher than the light-receiving surface 61. The retreat surface 62 is adjacent to the light-receiving surface 61. In the embodiment shown in FIG. 15, the retreat surface 62 is coupled to the light-receiving surface 61 and is inclined upward toward the outside of the transparent window 4.

The light-receiving surface 61 is located at the center of the lower surface of the transparent window 4, and the retreat surface 62 surrounds the light-receiving surface 61. In one embodiment, the retreat surface 62 has a shape of an inverted truncated cone. The light-receiving surface 61 is a flat surface and perpendicular to the orientation of the optical sensor head 25. The light-receiving surface 61 is perpendicular to the optical path of the light emitted from the optical sensor head 25, so that the light from the optical sensor head 25 is perpendicularly incident on the light-receiving surface 61. In one embodiment, a portion of the transparent window 4 that constitutes the retreat surface 62 may be made of a material different from the transparent material that constitutes the light-receiving surface 61.

If any bubbles are present on the light-receiving surface 61, the bubbles move from the light-receiving surface 61 to the retreat surface 62, and then move outward along the inclined retreat surface 62 and are collected on an outer region of the retreat surface 62. Therefore, the bubbles are removed from the light-receiving surface 61, and a stable optical path can be maintained. As a result, the optical film-thickness measuring system 20 can accurately measure the film thickness of the workpiece W.

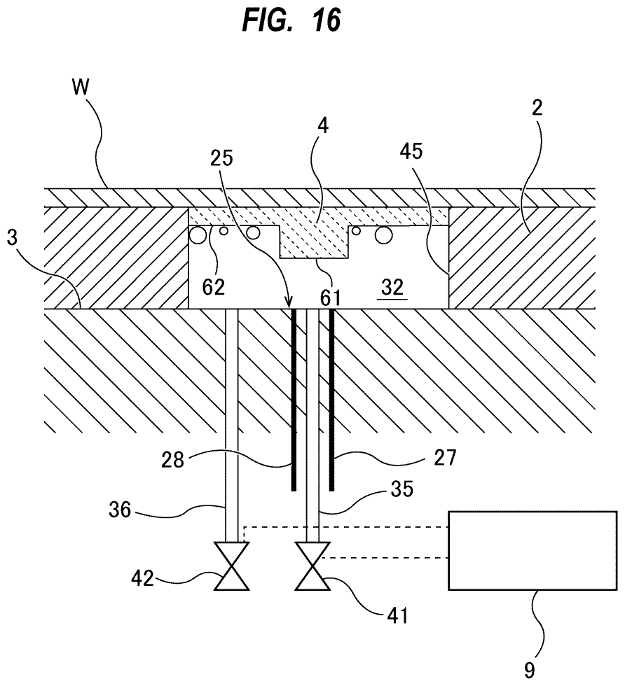

FIG. 16 is a cross-sectional view showing another embodiment of the transparent window 4. Configurations of this embodiment that not specifically described are the same as those of the embodiment described with reference to FIG. 15, and therefore duplicated descriptions thereof will be omitted. In the embodiment shown in FIG. 16, there is a step between the light-receiving surface 61 and the retreat surface 62. The retreat surface 62 is a flat surface that is located higher than the light-receiving surface 61. In one embodiment, the retreat surface 62 may be inclined upward toward the outside of the transparent window 4 as in the embodiment shown in FIG. 15, or may be curved upward toward the outside of the transparent window 4.

If any bubbles are present on the light-receiving surface 61, the bubbles move from the light-receiving surface 61 to the retreat surface 62 and are collected on the retreat surface 62. Therefore, the bubbles are removed from the light-receiving surface 61, and a stable optical path can be maintained. As a result, the optical film-thickness measuring system 20 can accurately measure the film thickness of the workpiece W.

The embodiments described with reference to FIGS. 15 and 16 are applicable to the embodiments described with reference to FIGS. 4 to 9.

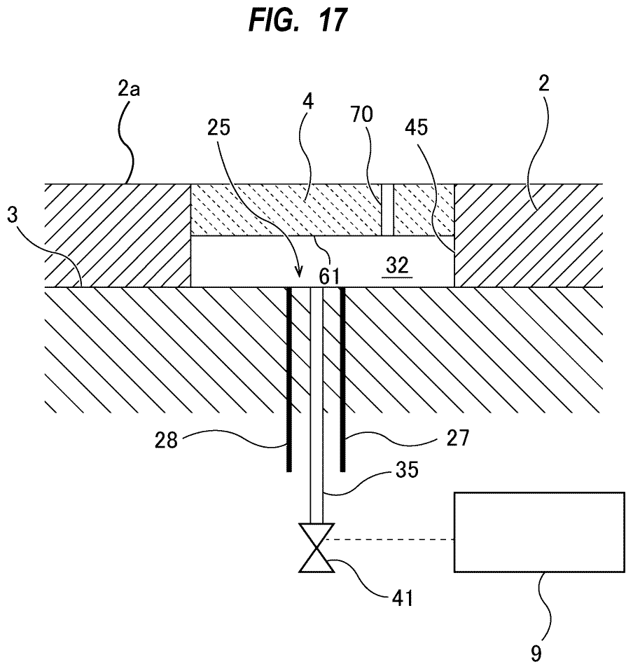

FIG. 17 is a cross-sectional view showing another embodiment of the polishing apparatus. Configurations of this embodiment that are not specifically described are the same as those of the embodiments described with reference to FIGS. 1 to 6, and therefore overlapping descriptions thereof will be omitted. In the embodiment shown in FIG. 17, the transparent window 4 has a transparent-liquid outlet 70 communicating with the space 32. The transparent-liquid outlet 70 is a through-hole penetrating the transparent window 4 and extends from the lower surface to the upper surface of the transparent window 4. The transparent-liquid outlet 70 is located outwardly of the light-receiving surface 61 configured to receive the light from the optical sensor head 25, and is away from the optical path. In this embodiment, the transparent-liquid discharge line 36 and the transparent-liquid discharge valve 42 are not provided.

During polishing of the workpiece W, the transparent-liquid supply valve 41 is opened, and pure water as the transparent liquid is supplied into the space 32 through the transparent-liquid supply line 35. The space 32 is filled with the pure water, and the pure water flows out of the space 32 through the transparent-liquid outlet 70. During polishing of the workpiece W, the transparent window 4 and the space 32 rotate together with the polishing table 3, so that there are times when the workpiece W is on the transparent window 4 and times when the workpiece W is not on the transparent window 4. When the workpiece W is not on the transparent window 4, the pure water in the space 32 flows out through the transparent-liquid outlet 70 onto the polishing pad 2. Therefore, a flow of the pure water is formed in the space 32. A flow rate of the pure water (transparent liquid) supplied into the space 32 through the transparent-liquid supply line 35 is such that a polishing rate of the workpiece W does not decrease due to dilution of the polishing liquid with the pure water on the polishing pad 2.

According to the present embodiment, if bubbles are present in the space 32, the bubbles are discharged from the space 32 through the transparent-liquid outlet 70 together with the pure water. Therefore, a stable optical path for measuring the film thickness of the workpiece W is ensured in the space 32. As a result, the optical film-thickness measuring system 20 can accurately measure the film thickness of the workpiece W. In one embodiment, the transparent window 4 may have a plurality of transparent-liquid outlets 70 communicating with the space 32.

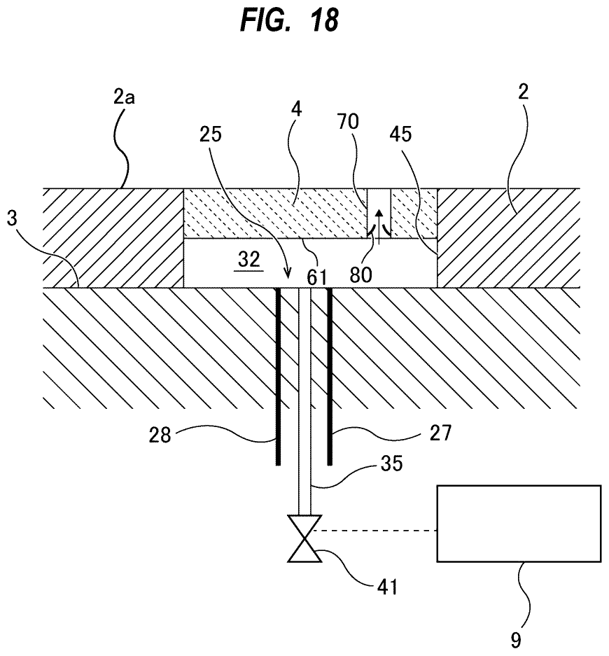

As shown in FIG. 18, in one embodiment, a check valve 80 coupled to the transparent-liquid outlet 70 may be provided. The check valve 80 is disposed in the polishing pad. In the embodiment shown in FIG. 18, the check valve 80 is disposed in the space 32. The check valve 80 is configured to allow the transparent liquid in the space 32 to flow out through the transparent-liquid outlet 70, while not allowing the transparent liquid to flow into the space 32 through the transparent-liquid outlet 70. For example, the check valve 80 is configured of a flap valve. The check valve 80 can prevent the polishing liquid on the polishing surface 2a of the polishing pad 2 and pure water used for dressing of the polishing pad 2 from flowing into the space 32.

The embodiments described with reference to FIGS. 17 and 18 may be applied to the embodiments described with reference to FIGS. 15 and 16. Specifically, the transparent-liquid outlet 70 may open in the retreat surface 62 shown in FIGS. 15 and 16.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing apparatus comprising:
a polishing pad having a transparent window configured to allow light to pass therethrough;
a polishing table supporting the polishing pad;
a polishing head configured to press a workpiece against the polishing pad; and
an optical film-thickness measuring system having an optical sensor head disposed below the transparent window, a space formed between the transparent window and the optical sensor head being filled with a transparent liquid.

2. The polishing apparatus according to claim 1, wherein the transparent window has a lower surface including a light-receiving surface configured to receive light from the optical sensor head and a retreat surface located higher than the light-receiving surface.

3. The polishing apparatus according to claim 2, wherein the retreat surface surrounds the light-receiving surface.

4. The polishing apparatus according to claim 1, further comprising a transparent-liquid supply line communicating with the space, the transparent window having a transparent-liquid outlet communicating with the space.

5. The polishing apparatus according to claim 1, further comprising a transparent-liquid supply line and a transparent-liquid discharge line communicating with the space, the transparent-liquid discharge line extending in the polishing table.

6. The polishing apparatus according to claim 5, further comprising:
a flow-rate measuring device provided in at least one of the transparent-liquid supply line and the transparent-liquid discharge line, the flow-rate measuring device being configured to measure a flow rate of the transparent liquid flowing through the transparent-liquid supply line; and
an operation controller electrically coupled to the flow-rate measuring device, the operation controller being configured to generate an alarm signal when a measured value of the flow rate of the transparent liquid falls outside a preset flow rate range.

7. The polishing apparatus according to claim 5, further comprising:
a pressure measuring device provided in at least one of the transparent-liquid supply line and the transparent-liquid discharge line, the pressure measuring device being configured to measure pressure of the transparent liquid flowing through the transparent-liquid supply line; and
an operation controller electrically coupled to the pressure measuring device, the operation controller being configured to generate an alarm signal when a measured value of the pressure of the transparent liquid falls outside a preset pressure range.

8. A transparent-liquid filling method comprising:
evacuating a space to form a negative pressure in a space that is formed between a transparent window constituting a part of a polishing pad for polishing a workpiece and an optical sensor head of an optical film-thickness measuring system for measuring a film thickness of the workpiece; and
supplying a transparent liquid into the space through a transparent-liquid supply line while the negative pressure is formed in the space.

9. The transparent-liquid filling method according to claim 8, wherein the transparent liquid is supplied into the space through the transparent-liquid supply line while the space is being evacuated.

10. The transparent-liquid filling method according to claim 8, wherein the transparent liquid is supplied into the space through the transparent-liquid supply line after the evacuation of the space is stopped and while the negative pressure is formed in the space.

11. The transparent-liquid filling method according to claim 8, further comprising stopping the supply of the transparent liquid into the space after the entire space is filled with the transparent liquid.
